(19) United States
(12) Patent Application Publication
(10) Pub. No.: US 2008/0259214 A1
(43) Pub. Date: Oct. 23, 2008

(54) VIDEO SIGNAL PROCESSING DEVICE, INTEGRATED CIRCUIT, AND IMAGING APPARATUS

(75) Inventors: Keiichi TSUMURA, Hyogo (JP); Shinji YAMAMOTO, Osaka (JP); Kenji NAKAMURA, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 12/103,434

(22) Filed: Apr. 15, 2008

(30) Foreign Application Priority Data
Apr. 17, 2007 (JP) 2007-107963
Apr. 9, 2008 (JP) 2008-101795

(51) Int. Cl. H03M 1/12

(52) U.S. Cl. 348/572

(57) ABSTRACT

Provided is a video signal processing device that can reduce power consumption within an analog signal processing unit not only during an invalid frame period of a video signal but also during a blanking period within a valid frame period, thus enabling further reduction of the power consumption. The video signal processing device that performs signal processing on an analog video signal inputted from outside includes: an analog signal processing unit including: a CDS/AGC unit that samples the analog video signal and amplifies the sampled analog video signal; and an AD converting unit that converts the resulting analog video signal from analog to digital, and a timing control unit that controls the analog signal processing unit to switch between an operating mode and a standby mode.

### BACKGROUND OF THE INVENTION

(1) Field of the Invention

The present invention relates to a video signal processing device that performs signal processing on an analog signal, and in particular to video signal processing in an imaging apparatus, such as a digital still camera and a video camera.

(2) Description of the Related Art

Conventionally, there is a technique for reducing power consumption in imaging apparatuses such as a digital still camera and a video camera, by operating an analog signal processing unit at a post stage for a valid frame period during which a video signal is outputted from an imaging unit, and by suspending an operation of the analog signal processing unit for an invalid frame period during which a video signal is not outputted from the imaging unit (see Japanese Unexamined Patent Application Publication No. 2001-145029 to be referred to as Patent Reference 1 hereinafter).

FIG. 1 illustrates an analog signal processing unit 404 in the imaging apparatus described in Patent Reference 1. The analog signal processing unit 404 includes a correlated dual sampling (CDS)/analog gain control (AGC) unit (hereinafter referred to as CDS/AGC unit) 401, an analog-to-digital converting unit (referred to as AD converting unit or simply as ADC unit) 402, and an analog clamp unit 403, and is controlled by a control signal inputted from a timing control unit 405. The timing control unit 405 outputs a power control signal S406 and an optical black (OB) clamp signal S404 indicating an OB period. Once an analog video signal S401 outputted from an imaging unit (not illustrated) is inputted in the CDS/AGC unit 401, the analog clamp unit 403 outputs, to the CDS/AGC unit 401, a clamp voltage S405 for controlling a level of the analog video signal S401 in the CDS/AGC unit 401 so that an OB value (optical black level) of the analog video signal for a period indicated by the OB clamp signal S404 matches a target value. With this, an analog video signal S402 in which OB level has been corrected is inputted in the ADC unit 402, and is outputted outside the analog signal processing unit 404 as a digital video signal S403. The power control signal S406 outputted from the timing control unit 405 turns on the analog signal processing unit 404 for a valid frame period, and turns off the analog signal processing unit 404 for an invalid frame period. As described above, power consumption is reduced by controlling power supplied to the analog signal processing unit 404.

In the imaging apparatus described in Patent Reference 1, power consumption can be reduced by suspending an operation in the analog signal processing unit 404 during the invalid frame period. Since an intermittent control in the analog signal processing unit 404 is performed on a frame-by-frame basis, neither an operation is suspended nor an operation is controlled during a period within a valid frame period when analog signal processing is not necessary, for example, during blanking periods (vertical and horizontal blanking periods). Thus, power consumption is not reduced during such blanking periods.

Here, it is conceivable to further reduce power consumption by cutting off power supplied to the analog signal processing unit 404 at a blanking period. However, in the technique of Patent Reference 1, when the analog signal processing unit 404 is switched from off to on, it requires a preparatory time so that the potential is restored to the level in which the analog signal processing unit 404 can operate with stability. Thus, when blanking periods start and the power is not supplied to the analog signal processing unit 404, there is a problem that the blanking periods end and the next valid frame period starts before the analog signal processing unit 404 resumes the normal operation. In other words, there is a problem, in the technique using power supply control as described in Patent Reference 1, that it is difficult to reduce power consumption at a blanking period, and it is not possible to further reduce power consumption in a conventional video signal processing device.

### SUMMARY OF THE INVENTION

The present invention has an object of providing a video signal processing device, an imaging apparatus, and the like which are capable of reducing power consumption in the analog signal processing unit not only during an invalid frame period of a video signal but also during a blanking period within a valid frame period, and thus capable of further reducing the power consumption.

The video signal processing device and the imaging apparatus according to the present invention can suspend an operation of the analog signal processing unit by going into a standby mode, not into an off mode. In other words, the power consumed in the analog signal processing unit is reduced by suspending an operation (analog signal processing), while holding a power supply voltage supplied to the analog signal processing unit and an internal voltage in the analog signal processing unit. Since the switching between the standby mode and the operating mode can be performed in higher speed than the speed of turning the power on and off, it is possible to switch between a suspension mode and an operating mode in the analog signal processing unit without delay not only during an invalid frame period but also during a blanking period within a valid frame period, and to further reduce power consumption.

In other words, the video signal processing device according to the present invention is a video signal processing device that performs signal processing on an analog video signal inputted from outside, and includes: an analog signal processing unit including: a CDS/AGC unit that samples the analog video signal and amplifies the sampled analog video signal; and an AD converting unit that converts the resulting analog video signal outputted from the CDS/AGC unit from analog to digital; and a timing control unit that controls the analog signal processing unit to switch between an operating mode and a standby mode. With this, when the analog signal processing is not necessary, the power is gone into the standby mode, not turning the power off. Thus, it becomes possible to reduce power consumption during a blanking period that is an extremely short period of time.

Here, the video signal processing device may further include an analog clamp unit that outputs a clamp voltage for maintaining an optical black level of the analog video signal, wherein the CDS/AGC unit may sample the analog video signal and amplify the sampled analog video signal based on the clamp voltage, and may further include: an optical black level correction unit that obtains a digital optical black level correcting value for maintaining the optical black level, by sampling a value of the digital video signal during an optical black level period; and a DA converting unit that converts the digital optical black level correcting value obtained by the optical black level correction unit to an analog optical black level correcting value, and the analog clamp unit may output the clamp voltage based on the analog optical black level correcting value outputted from the DA converting unit. With this, even when an additional constituent element is added to the analog signal processing unit, power consumption can be reduced in the standby mode.

More specifically, in the standby mode, the analog signal processing unit suspends analog signal processing while holding an internal signal. For example, the analog signal processing unit holds, as the internal signal held in the standby mode, at least one of: a power supply voltage supplied to the analog signal processing unit; the clamp voltage outputted by the analog clamp unit; a reference voltage generated within the AD converting unit; and a reference voltage generated within the DA converting unit. Alternatively, the analog signal processing unit cuts off a clock signal without cutting off power in the standby mode, the clock signal and the power being supplied to the CDS/AGC unit, the AD converting unit, the analog clamp unit, and the DA converting unit.

With this, the timing control unit can control the analog signal processing unit to go into the standby mode plural times during one frame period of the analog video signal. Furthermore, the timing control unit can control the analog signal processing unit to go into the standby mode during an invalid frame period of the analog video signal and during a blanking period within a valid frame period of the analog video signal.

Note that the present invention can be implemented not only as such a video signal processing device but also as: a semiconductor integrated circuit, such as an LSI, which includes the video signal processing device having the aforementioned configuration; and an imaging apparatus, such as a digital camera, which includes a lens, an imaging unit that converts light that passes through the lens into an analog video signal, and the aforementioned video signal processing device that performs signal processing on an analog video signal outputted from the imaging unit.

The present invention can provide an video signal processing device that can reduce power consumption by not only operating and suspending the analog signal processing unit on a frame-by-frame basis but also suspending the unit during a period shorter than one frame, for example, during a blanking period within a valid frame period. Furthermore, the present invention can provide an LSI and an imaging apparatus of low power consumption which include such a video signal processing device. In particular, practicality of the present invention is extremely high because it can further reduce power consumption of a mobile device, today when battery-powered and hand-held devices including imaging apparatuses are widely available.

### FURTHER INFORMATION ABOUT TECHNICAL BACKGROUND TO THIS APPLICATION

The disclosure of Japanese Patent Application No. 2007-107963 filed on Apr. 17, 2007 and No. 2008-101795 filed on Apr. 9, 2008 each including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 illustrates an analog signal processing unit in a conventional imaging apparatus.

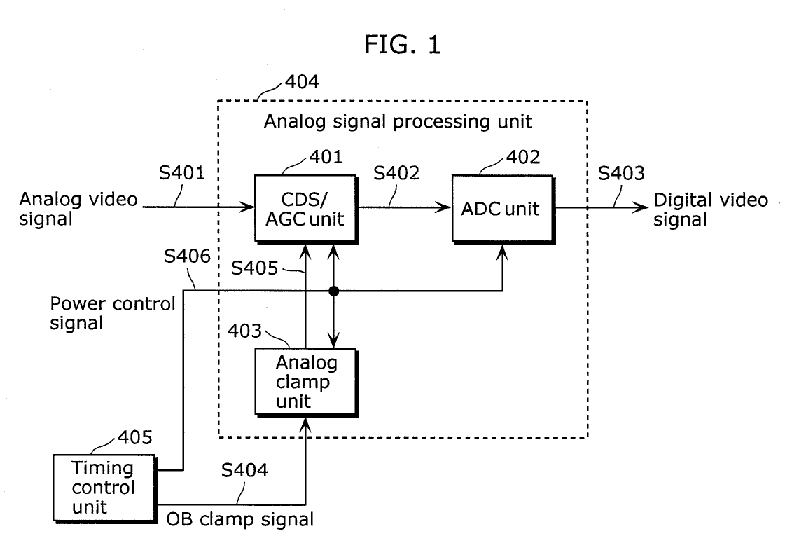

FIG. 2 illustrates the configuration of the video signal processing device according to the first embodiment.

FIG. 3 illustrates blanking periods and OB periods.

FIG. 4 illustrates an example of a method for going into a standby mode.

FIG. 5 illustrates another example of a method for going into a standby mode.

FIG. 6(a) is a timing chart illustrating a standby mode of the video signal processing device of the first embodiment, and FIG. 6(b) is a timing chart illustrating a standby mode of a conventional video signal processing device.

FIG. 7 illustrates the configuration of the video signal processing device according to the second embodiment.

FIG. 8 illustrates the configuration of the imaging apparatus according to the second embodiment.

### DESCRIPTION OF THE PREFERRED EMBODIMENTS

The embodiments of the present invention are to be described hereinafter.

### First Embodiment

First, the video signal processing device in the first embodiment of the present invention is described.

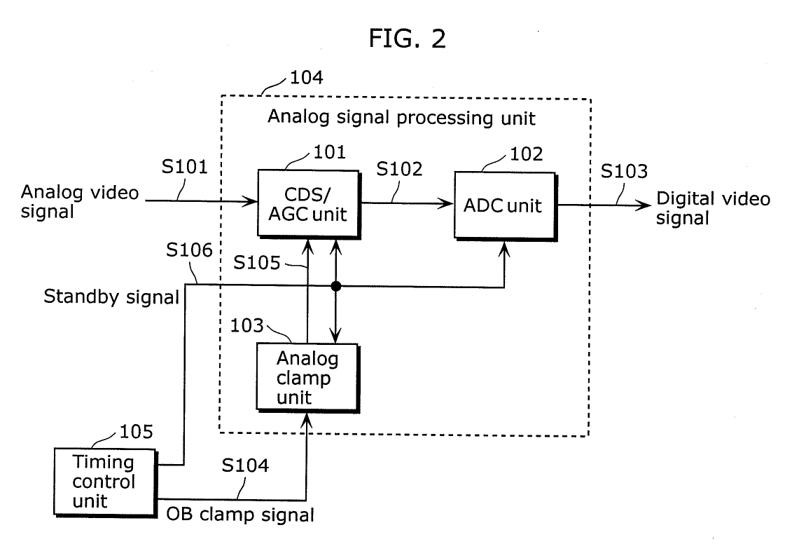

FIG. 2 illustrates the configuration of the video signal processing device according to the first embodiment. This video signal processing device is a semiconductor integrated circuit, for example LSI, which performs signal processing, such as noise removal, amplification, and A/D conversion, on an analog video signal inputted from outside (imaging unit). The device includes an analog signal processing unit 104 and a timing control unit 105.

The analog signal processing unit 104 is a circuit that outputs a digital video signal S103 by performing various signal processing on an analog video signal S101 outputted from an imaging unit typified by a CCD and a MOS sensor. The unit includes a CDS/AGC unit 101, an ADC unit 102, and an analog clamp unit 103.

The CDS/AGC unit 101 is composed of two circuits, namely, a CDS circuit and an AGC circuit, for sampling and amplifying the analog video signal S101, respectively. The CDS circuit is a correlated dual sampling circuit that prevents an effect of a reset noise by sampling a difference between a reset level and a pixel level of the imaging unit that are indicated by the inputted analog video signal S101. The AGC circuit is an analog gain control circuit that functions as a variable gain amplifier that amplifies the signal outputted from the CDS circuit, according to the signal.

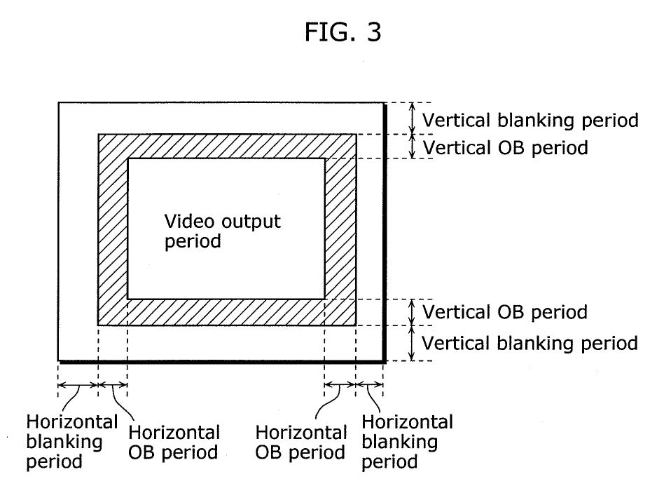

The timing control unit 105 generates an OB clamp signal S104 indicating an OB period and a standby signal S106 indicating a standby period which is a control signal for controlling the analog signal processing unit 104 to be switched between an operating mode and a standby mode, and outputs the respective signals to the analog signal processing unit 104. Note that a standby period is a period during which analog signal processing is not necessary. In the first embodiment, the standby period corresponds to an invalid frame period during which an analog video signal is not outputted from an imaging unit, and also to a blanking period within a valid frame period during which an analog video signal is outputted from an imaging unit. The invalid frame period is a frame period during which: frames are decimated at regular intervals for generating a video signal at low frame rate; images are intermittently taken; and an image is taken only when a user instructs the taking of the image. Blanking periods include vertical blanking periods and horizontal blanking periods as illustrated in FIG. 3. Furthermore, as illustrated in FIG. 3, an OB period is a period during which a optical black signal is outputted from an imaging unit, and OB periods include a vertical OB period and a horizontal OB period. The analog clamp unit 103 is a circuit that outputs a clamp voltage for maintaining the optical black level of the analog video signal S102 outputted from the CDS/AGC unit 101. More specifically, the analog clamp unit 103 outputs the clamp voltage S105 to the CDS/AGC unit 101 for controlling the level of the analog video signal in the CDS/AGC unit 101 so that the OB value during a period indicated by the OB clamp signal S104 meets the target value. With this, the analog video signal S102 in which OB level( [symbol] ) correction has been performed is inputted to the ADC unit 102. The ADC unit 102 converts the inputted analog video signal S102 to the digital video signal S103, and outputs the signal S103 outside the analog signal processing unit 104.

An operation of the analog signal processing unit 104 in the video signal processing device having the aforementioned configuration is suspended as follows. The standby signal S106 is outputted from the timing control unit 105 to the analog signal processing unit 104 at a timing when an invalid period starts during which the analog video signal S101 is not outputted from the imaging unit, in other words, at a timing when a period starts during which analog signal processing is not necessary (an invalid frame period and a blanking period within a frame period in the first embodiment). In response to the standby signal S106, the CDS/AGC unit 101, the ADC unit 102, and the analog clamp unit 103 within the analog signal processing unit 104 immediately suspend respective operations (analog signal processing), and switch to the standby mode.

The standby mode in the first embodiment refers to suspension of analog signal processing while the analog signal processing unit 104 holds an internal signal. Here, the internal signal in the standby mode that are held in the analog signal processing unit 104 includes at least one of a power supply voltage supplied to the analog signal processing unit 104, the clamp voltage S105 outputted from the analog clamp unit 103, and a reference voltage generated within the ADC unit 102. In the first embodiment, the analog signal processing unit 104 holds the power supply voltage supplied to the analog signal processing unit 104, the reference voltage generated from the power supply voltage, and the clamp voltage S105.

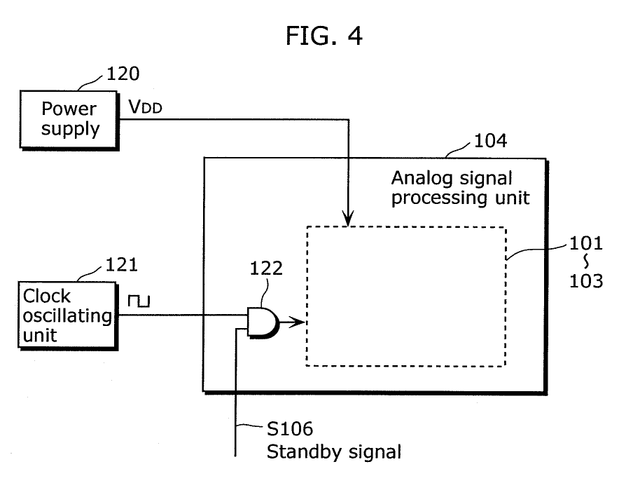

FIG. 4 illustrates an example of a method for going into a standby mode. Here, in the standby mode, the analog signal processing unit 104 cuts off a clock signal without cutting off power supplied to the units 101 to 103. In other words, the analog signal processing unit 104 cuts off a clock signal to the units 101 to 103 by turning off a switch 122 of a gate circuit and the like connected between a clock oscillating unit 121 and each of the units 101 to 103, without cutting off a power supply voltage supplied from a power supply 120 to the units 101 to 103 during a standby period indicated by the standby signal S106.

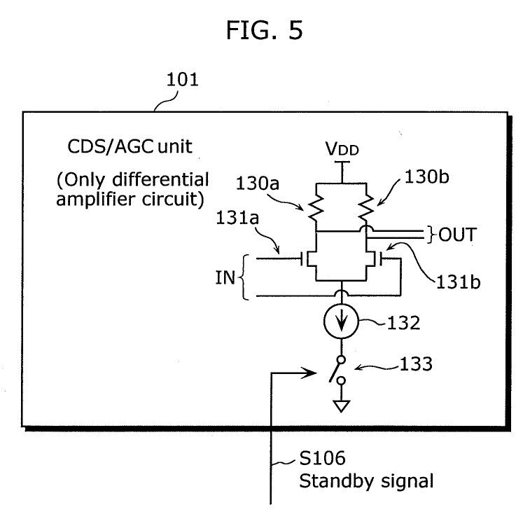

FIG. 5 illustrates another example of a method for going into a standby mode. Here, the AGC circuit in the CDS/AGC unit 101 suspends an operation (amplification herein) in a standby mode. In other words, the AGC circuit in the CDS/AGC unit 101 includes a differential amplifier circuit including load resistors 130a and 130b, a pair of MOS transistors 131a and 131b each coupled to a source electrode of the transistor, a constant current source 132, and a switch 133. The switch 133 is a MOS transistor and the like, and is off during a standby period indicated by the standby signal S106. As such, the CDS/AGC unit 101 suspends an operation without cutting off a power supplied to an internal circuit.

Then, immediately before the end of the invalid period, the standby signal S106 is negated, the analog signal processing unit 104 immediately switches from the standby mode to the operating mode. Since the switching operation between the standby mode and the operating mode is performed in high speed, it is possible to resume the operation of the analog signal processing unit 104 without delay at a timing when a video signal is switched to a valid frame. When blanking intermittently occurs plural times during the valid frame, each time the mode is switched between the standby mode and the operating mode.

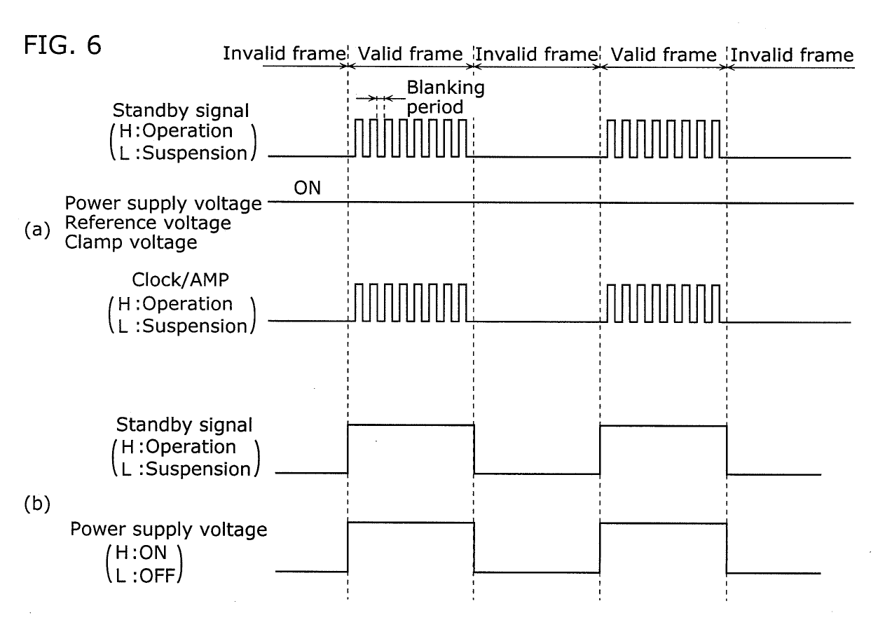

FIG. 6(a) is a timing chart illustrating a standby mode of the video signal processing device of the first embodiment, and FIG. 6(b) is a timing chart illustrating a standby mode of a conventional video signal processing device.

As illustrated in FIG. 6(a), the standby signal S106 outputted from the timing control unit 105 becomes low during invalid frame periods and blanking periods within valid frame periods, which are standby periods. The analog signal processing unit 104 holds a power supply voltage supplied to the analog signal processing unit 104, a reference voltage generated from the power supply voltage, and the clamp voltage S105 regardless of a state of a standby signal (high/low), and only when a standby signal is low, it suspends an operation (analog signal processing) in each of the units 101 to 103 by cutting off a clock signal supplied to each of the units 101 to 103 and a constant current source in the differential amplifier circuit.

On the other hand, in the conventional video signal processing device, as illustrated in FIG. 6(b), the standby signal becomes low only during an invalid frame period as a standby period, and the power supply to the analog signal processing unit 104 is suspended only during the period.

As described above, the video signal processing device of the first embodiment can suspend an operation of the analog signal processing unit 104 not only during an invalid frame period but also during a blanking period within a valid frame period, thus, enabling further reduction of power consumption.

Note that although the analog signal processing unit 104 includes the analog clamp unit 103 in the first embodiment, the analog signal processing unit according to the present invention does not necessarily have to include such analog clamp unit. This is because according to the present invention, power consumption can be reduced by controlling the analog signal processing unit to go into a standby mode not only during an invalid frame period but also during a blanking period within a valid frame period, regardless of the presence or absence of the analog clamp unit 103.

### Second Embodiment

Next, the video signal processing device in the second embodiment of the present invention is described.

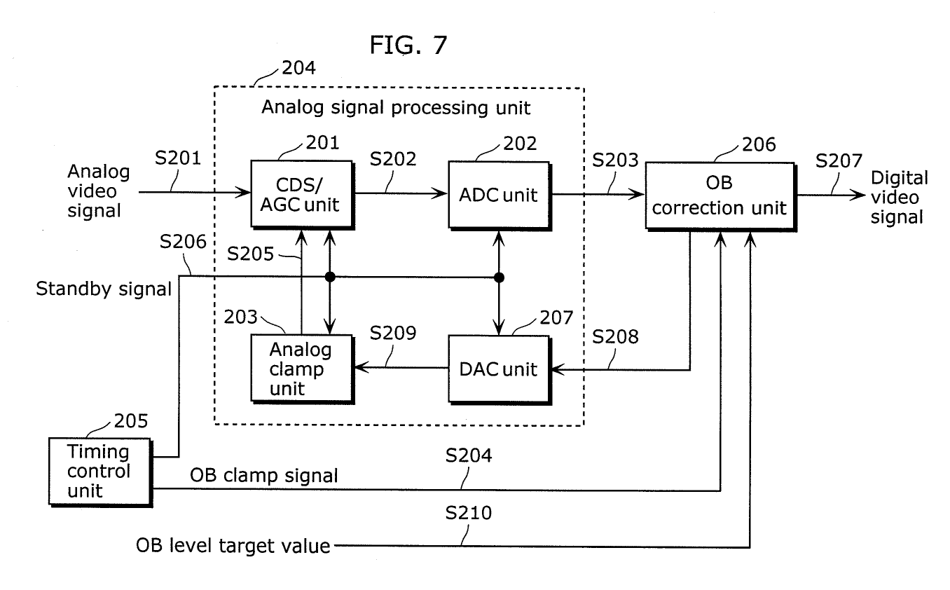

FIG. 7 illustrates the configuration of the video signal processing device according to the second embodiment. This video signal processing device is a semiconductor integrated circuit, for example LSI, which performs signal processing, such as noise removal, amplification, and A/D conversion, on an analog video signal inputted from outside (imaging unit). The device includes an analog signal processing unit 204, a timing control unit 205, and an OB correction unit 206. In the video signal processing device having the configuration illustrated in FIG. 7, it is possible to reduce power consumption as the video signal processing device described in the first embodiment.

The analog signal processing unit 204 is a circuit that outputs a digital video signal S203 by performing various signal processing on an analog video signal S201 outputted from an imaging unit typified by a CCD and a MOS sensor. The unit includes a CDS/AGC unit 201, an ADC unit 202, an analog clamp unit 203, and a DAC unit 207.

The CDS/AGC unit 201 has the same function as that of the CDS/AGC unit 101 in the first embodiment, amplifies the analog video signal S201 in which correlated dual sampling has been performed, and outputs the amplified signal as an analog video signal S202.

The ADC unit 202 has the same function as that of the ADC unit 102 in the first embodiment, converts the analog video signal S202 outputted from the CDS/AGC unit 201 from analog to digital, and outputs the digital signal as an digital video signal S203 to the OB correction unit 206.

The timing control unit 205 generates an OB clamp signal S204 indicating an OB period and a standby signal S206 indicating a standby period in the second embodiment as generated in the first embodiment. Additionally, the timing control unit 205 outputs the OB clamp signal S204 to the OB correction unit 206 and the standby signal S206 to the analog signal processing unit 204.

Once the OB correction unit 206 receives the digital video signal S203 from the ADC unit 202, it calculates an OB correcting value so that a video signal for use during a period indicated by the OB clamp signal S204 matches an OB value indicated by the predetermined OB level target value S210, and outputs the calculated OB correcting value as a digital OB correcting value S208.

The DAC unit 207 is a D/A converter, thus converting the digital OB correcting value S208 outputted from the OB correction unit 206 to an analog OB correcting value S209, and feeding back the value to the analog clamp unit 203.

The analog clamp unit 203 basically has the same function as that of the analog clamp unit 103 in the first embodiment. In the second embodiment, the analog clamp unit 203 controls a level of an analog video signal in the CDS/AGC unit 201 based on the analog OB correcting value S209 outputted from the DAC unit 207 so that an OB value for use during a period indicated by the OB clamp signal S204 matches a target value.

The ADC unit 202 converts the analog video signal S202 outputted from the CDS/AGC unit 201 to the digital video signal S203, and outputs the digital video signal S203. The digital video signal S203 outputted from the ADC unit 202 is outputted as the corrected digital video signal S207 via the OB correction unit 206.

Since the aforementioned configuration enables the analog clamp unit 203 to analogously control an OB level and the OB correction unit 206 to digitally fine control an OB level, it becomes possible to control the OB level more precisely.

An operation of the analog signal processing unit 204 in the video signal processing device having the aforementioned configuration is suspended as follows. The standby signal S206 is outputted from the timing control unit 205 to the analog signal processing unit 204 at a timing when an invalid period starts during which the analog video signal S201 is not outputted from the imaging unit, in other words, at a timing when a period starts during which analog signal processing is not necessary (an invalid frame period and a blanking period within a frame period in the present embodiment). In response to the standby signal S206, the CDS/AGC unit 201, the ADC unit 202, the analog clamp unit 203, and the DAC unit 207 within the analog signal processing unit 204 immediately suspend respective operations (analog signal processing), and switch to the standby mode.

The standby mode in the second embodiment refers to suspension of analog signal processing while the analog signal processing unit 104 holds an internal signal as in the first embodiment. Here, the internal signal at the standby mode that is held in the analog signal processing unit 204 includes at least one of a power supply voltage supplied to the analog signal processing unit 204, a clamp voltage S205 outputted from the analog clamp unit 203, a reference voltage generated within the ADC unit 202, and a reference voltage generated within the DAC unit 207. In the second embodiment, the analog signal processing unit 204 holds the power supply voltage supplied to the analog signal processing unit 204, the reference voltage generated from the power supply voltage, and the clamp voltage S205. Note that the specific method for going into a standby mode is the same as that of the first embodiment.

Then, immediately before the end of the invalid period, the standby signal S206 is negated, the analog signal processing unit 204 immediately switches from the standby mode to the operating mode. Since the switching operation between the standby mode and the operating mode is performed in high speed, it is possible to resume the operation of the analog signal processing unit 204 without delay at a timing when a video signal is switched to a valid frame. When blanking intermittently occurs plural times during the valid frame period, each time the mode is switched between the standby mode and the operating mode.

As described above, the video signal processing device of the second embodiment can suspend an operation of the analog signal processing unit 204 not only during an invalid frame period but also during a blanking period within a valid frame period, thus, enabling further reduction of power consumption.

Note that since the aforementioned embodiments are mere examples of the present invention, the present invention is not limited to the first and second embodiments. The present invention includes an embodiment obtained by modifying the aforementioned embodiments and an embodiment in which the aforementioned constituent elements are arbitrarily combined.

For example, the present invention may include a setting unit which can set an OB clamp signal and an OB level target value for each operating mode of an imaging unit and for each category of imaging units. Furthermore, a unit that controls the analog signal processing unit to go into a standby mode may be provided in any manner.

As described above, the present invention can suspend an operation of an analog signal processing unit not only during an invalid frame period but also during a blanking period within a valid frame period by, in the standby mode, switching between a standby mode and an operating mode in high speed while holding an internal voltage of the analog signal processing unit, and thus, reducing more power consumption than the conventional video signal processing device.

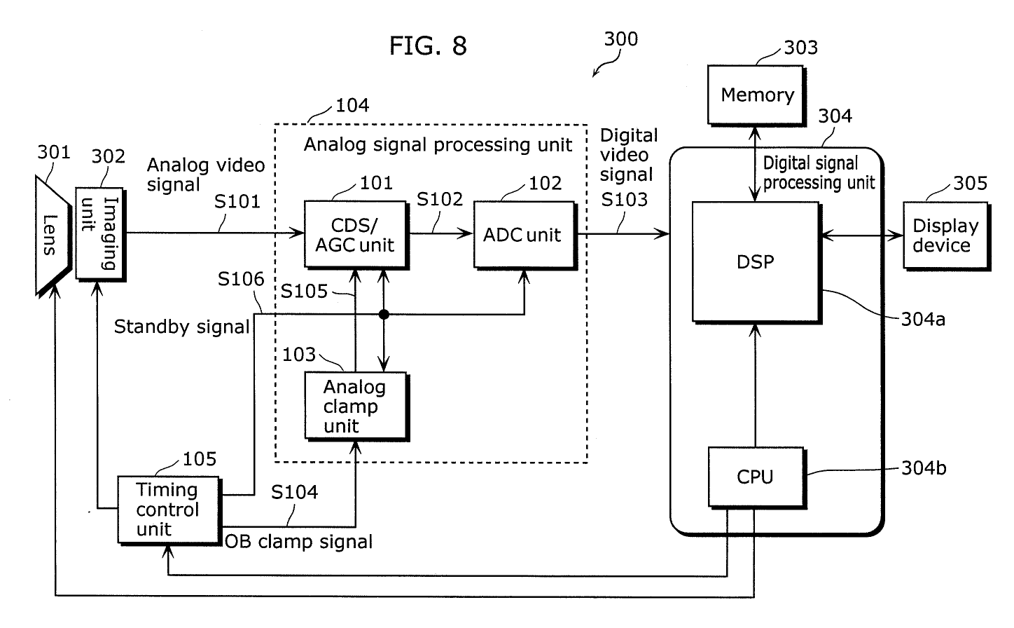

Note that the present invention can be implemented not only as an video signal processing device as described in the aforementioned embodiments, but also as an imaging apparatus, such as a digital camera. FIG. 8 illustrates the configuration of an imaging apparatus 300 which includes the video signal processing device according to the first embodiment and can reduce power consumption. This imaging apparatus 300 includes a lens 301, an imaging unit 302, a memory 303, a digital signal processing unit 304, and a display device 305 in addition to the video signal processing device according to the first embodiment.

The lens is an optical element that collects light. The imaging unit 302 is a sensor, such as a CCD or a C-MOS sensor, which converts light that passes through the lens 301 to an analog video signal. The memory 303 is, for example, a DRAM, which stores an image. The display device 305 is, for example, a liquid crystal display (LCD), which displays the image. The digital signal processing unit 304 generates image data by performing signal processing, such as color control and compression, on the digital video signal S103 outputted from the analog signal processing unit 104, and includes a digital signal processor (DSP) 304a that stores the image data in the memory 303 and outputs the data to the display device 305, and a CPU 304b that controls each of the constituent elements of the digital signal processing unit 304.

Such imaging apparatus 300 can suspend an operation of the analog signal processing unit 104 not only during invalid frame period but also a blanking period within a valid frame period, thus reducing more power consumption than the conventional imaging apparatus.

Note that a video signal processing device included in an imaging apparatus is not limited to the video signal processing device according to the first embodiment, and obviously, the device may be the video signal processing device according to the second embodiment and a device obtained by modifying the aforementioned video signal processing devices.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to general imaging apparatuses, for example, a digital still camera, a video camera, a television, and a camera for medical use, as a video signal processing device that performs signal processing on an analog signal and as an imaging apparatus including such video signal processing device. In particular, the present invention is effectively used for reducing power consumption in a device having long invalid periods of a video signal, such as a capsule camera device for medical use that intermittently takes images.

What is claimed is:

1. A video signal processing device that performs signal processing on an analog video signal inputted from outside, said device comprising:
an analog signal processing unit including:
a CDS/AGC unit operable to sample the analog video signal and to amplify the sampled analog video signal; and
an AD converting unit operable to convert the resulting analog video signal outputted from said CDS/AGC unit from analog to digital; and
a timing control unit operable to control said analog signal processing unit to switch between an operating mode and a standby mode.

2. The video signal processing device according to claim 1, further comprising
an analog clamp unit operable to output a clamp voltage for maintaining an optical black level of the analog video signal,
wherein said CDS/AGC unit is operable to sample the analog video signal and amplify the sampled analog video signal based on the clamp voltage.

3. The video signal processing device according to claim 2,
wherein said analog signal processing unit further includes:
an optical black level correction unit operable to obtain a digital optical black level correcting value for maintaining the optical black level, by sampling a value of the digital video signal during an optical black level period; and
a DA converting unit operable to convert the digital optical black level correcting value obtained by said optical black level correction unit to an analog optical black level correcting value, and
said analog clamp unit is operable to output the clamp voltage based on the analog optical black level correcting value outputted from said DA converting unit.

4. The video signal processing device according to claim 3,
wherein said analog signal processing unit is operable, in the standby mode, to suspend analog signal processing while holding an internal signal.

5. The video signal processing device according to claim 4,
wherein said analog signal processing unit holds, as the internal signal held in the standby mode, at least one of: a power supply voltage supplied to said analog signal processing unit; the clamp voltage outputted by said analog clamp unit; a reference voltage generated within said AD converting unit; and a reference voltage generated within said DA converting unit.

6. The video signal processing device according to claim 4,
wherein said analog signal processing unit is operable to cut off a clock signal without cutting off power in the standby mode, the clock signal and the power being supplied to said CDS/AGC unit, said AD converting unit, said analog clamp unit, and said DA converting unit.

7. The video signal processing device according to claim 1,
wherein said timing control unit is operable to control said analog signal processing unit to go into the standby mode plural times during one frame period of the analog video signal.

8. The video signal processing device according to claim 1,
wherein said timing control unit is operable to control said analog signal processing unit to go into the standby mode during an invalid frame period of the analog video signal and during a blanking period within a valid frame period of the analog video signal.

9. A semiconductor integrated circuit comprising
a video signal processing device including a video signal processing device that performs signal processing on an analog video signal inputted from outside,
wherein said video signal processing device includes:
an analog signal processing unit including:
a CDS/AGC unit operable to sample the analog video signal and to amplify the sampled analog video signal; and
an AD converting unit operable to convert the resulting analog video signal outputted from said CDS/AGC unit from analog to digital; and
a timing control unit operable to control said analog signal processing unit to switch between an operating mode and a standby mode.

10. An imaging apparatus comprising:
a lens;
an imaging unit operable to convert light that passes through said lens to an analog video signal; and
a video signal processing device that performs signal processing on the analog video signal outputted from said imaging unit,
wherein said video signal processing device includes:
an analog signal processing unit including:
a CDS/AGC unit operable to sample the analog video signal and to amplify the sampled analog video signal; and
an AD converting unit operable to convert the resulting analog video signal outputted from said CDS/AGC unit from analog to digital; and
a timing control unit operable to control said analog signal processing unit to switch between an operating mode and a standby mode.
